(19) United States
(12) Patent Application Publication
(10) Pub. No.: US 2002/0027017 A1
(43) Pub. Date: Mar. 7, 2002

(54) Circuit board standoff

(76) Inventor: Hector D. Petri, Framingham, MA (US)

Correspondence Address: JOHN E. TOUPAL, 116 CONCORD STREET, FRAMINGHAM, MA, 01701

(21) Appl. No.: 09/938,198

(22) Filed: Aug. 23, 2001

Related U.S. Application Data
(63) Continuation of application No. 09/654,361, filed on Sep. 1, 2000, now abandoned.

(51) Int. Cl. H05K 1/00

(52) U.S. Cl. 174/250

(57) ABSTRACT

A circuit board standoff including a fastener mechanism and a body for disposition between first and second boards and having an upper portion for contacting the first board, fastener portions for engaging the fastener to secure the body to the first board and engagement portions arranged to be forced into penetrating engagement with the second board.

This application is a continuation of co-pending application Ser. No. 09/654,361 filed Sep. 1, 2000, entitled Circuit Board Standoff.

### BACKGROUND OF THE INVENTION

This invention relates generally to electrical circuit board apparatus and, more particularly, to improved standoff elements for separating and supporting printed circuit boards.

Printed circuit boards are used extensively in various types of electrical equipment. Typically, standoff elements are used to support and provide spacing for circuit boards. Standoffs are used, for example, to separate, support and electrically insulate a printed circuit board from either a metal chassis or other printed circuit boards. In many applications, separated circuit boards include ground circuits that must be interconnected. Standoff elements of that type are disclosed, for example, in U.S. Pat. Nos. 4,952,158; 5,281,149; 5,345,366 and 5,380,211. Such prior standoff elements exhibit certain deficiencies such as structural complexity, limited specialized use and high cost.

The object of this invention, therefore, is to provide an improved standoff device that can both separate and electrically ground printed circuit boards.

### SUMMARY OF THE INVENTION

The invention is a circuit board standoff including a fastener mechanism and a body for disposition between first and second boards and having an upper portion for contacting the first board, fastener portions for engaging the fastener mechanism to secure the body to the first board, and engagement portions arranged to be forced into penetrating engagement with the second board. The engagement portions facilitate securement of a structurally simple standoff between the first and second boards.

According to one feature of the invention, the body further includes a plurality of legs having lower portions shaped and arranged to be tightly received by an opening in the second board and defining the engagement portions. The legs can be expanded to penetrate the second board.

According to another feature of the invention, the engagement portions are defined by extremity portions of the legs, the extremity portions being shaped and arranged for outward expansion to penetrate perimeter portions of the opening in the second board. The extremity portions are expanded to penetrate the second board and secure the body thereto.

According to an important feature of the invention, the fastener mechanism produces outward expansion of the legs in response to engagement with the fastener portions. The outward expansion maintains the penetrating engagement between the engagement portions and second board.

According to yet another feature of the invention, the legs include at least one leg in which the lower portion thereof is outwardly convex and has opposite edge portions defining the extremity portions. The concave legs provide the engagement portions in a simple, easily fabricated structure.

According to still another feature of the invention, the legs include at least one leg in which the lower portion thereof defines outwardly directed engagement tabs further defining the extremity portions. The tabs further secure the body to the second board.

According to an additional feature of the invention, the legs include at least one leg in which said lower portion thereof defines an outwardly directed flange shaped and arranged to engage a surface of the second board facing opposite to the first board. The flange assists in positioning and retaining the body in the opening of the second board.

According to a further feature of the invention, the fastener mechanism is a screw having a threaded shank engaging the fastener portions and a head for contacting a surface of the first board facing opposite to the second board. The screw secures the body to the first board.

According to another feature of the invention, the fastener portions include an inwardly directed annular collar in the upper portion and having an inner fastener edge threadedly engaged with the threaded shank.

According to yet another feature of the invention, the fastener portions also include inwardly directed fastener tabs formed in an intermediate portion of the body and threadedly engaged with the threaded shank.

According to an important feature of the invention, the body is a substantially cylindrical, unitary member stamped from an electrically conductive material. The provision of a unitary stamped body reduces the cost of the standoff.

### DESCRIPTION OF THE DRAWINGS

These and other objects and features of the invention will become more apparent upon a perusal of the following description taken in conjunction with the accompanying drawings wherein:

FIG. 1 is a perspective view of a standoff according to the invention;

FIG. 2 is a top view of the standoff illustrated in FIG. 1;

FIG. 3 is a cross-sectional view taken along lines 3-3 of FIG. 2;

FIG. 4 is a cross-sectional view taken along lines 4-4 of FIG. 2;

FIG. 5 is a perspective view of another standoff embodiment of the invention;

FIG. 6 is a top view of the standoff illustrated in FIG. 5; and

FIG. 7 is a cross-sectional view taken along lines 7-7 of FIG. 6.

### DESCRIPTION OF THE PREFERRED EMBODIMENTS

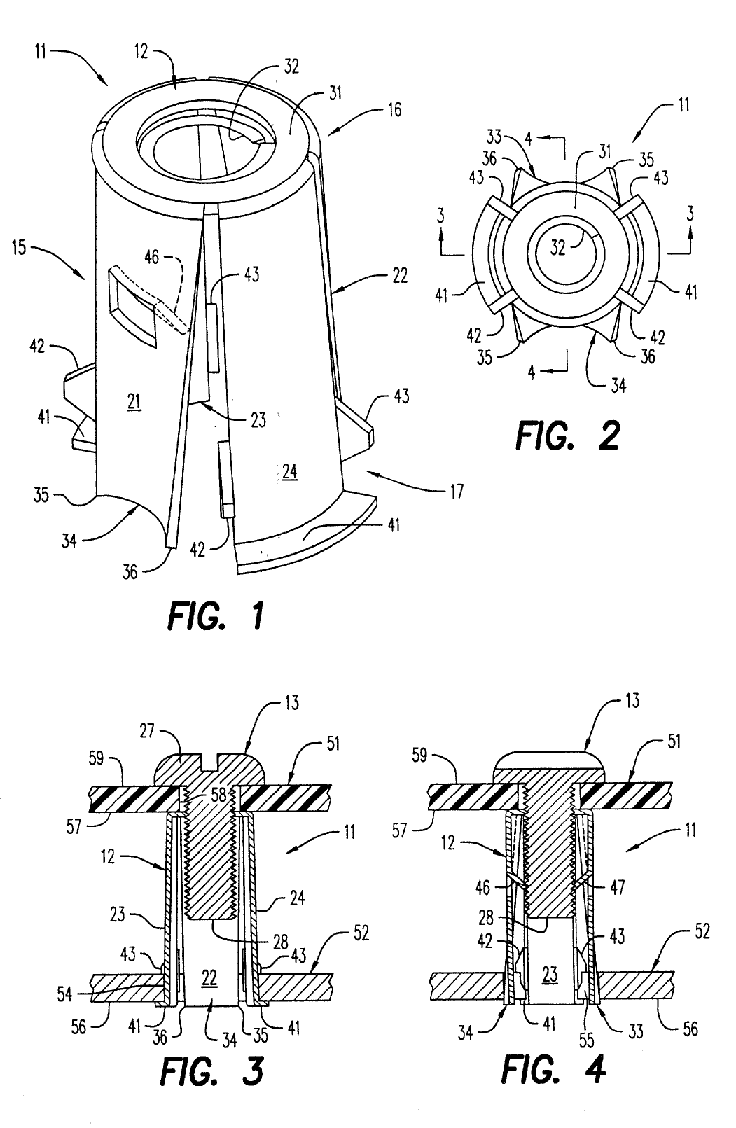

A standoff 11 includes a body 12 (FIG. 1) and a screw faster 13 (FIGS. 3 and 4). The body 12 is a substantially cylindrical member having an intermediate portion 15 straddled by an upper portion 16 and a lower portion 17. Preferably, the body 12 is a unitary member stamped from a suitable electrically conductive, spring tempered material such as electro-tin plated carbon steel. Forming the body 12 are a first pair of diametrically opposed legs 21, 22 separated by a second pair of diametrically opposed legs 23, 24. The screw fastener 13 has a slotted head 27 and a threaded shank portion 28 as shown in FIGS. 3 and 4.

Defined by the upper portion 16 of the body 12 is an annular inwardly directed collar 31 terminating with a fastener helical edge 32 shaped and dimensioned for threaded engagement with the shank portion 28 of the screw fastener 13. Each of the first pair of legs 21, 22 has an outwardly convex lower portion 34 with circumferentially spaced apart lower opposite edge extremities which define engagement portions 35, 36. A flange 41 is directed outwardly at the bottom of each of the second pair of legs 23, 24. Closely adjacent to the flange 41 in each of the second pair of legs 23, 24 are a pair of circumferentially spaced apart engagement tabs 42, 43 directed outwardly from lower edges of each of the second pair of legs 23, 24. Extremity edges of the tabs 42, 43 form additional engagement portions of the body 12. Also formed in intermediate portions of each of the first pair of legs 21, 22, respectively, are inwardly directed fastener tabs 46, 47, dimensioned and arranged for threaded engagement with the shank portion 28 of the screw fastener 13.

A plurality of spaced apart standoffs 11 are used to maintain separation between a pair of boards. Typically, each standoff 11 is positioned between a first printed circuit board 51 and a sheet metal baseboard 52 as depicted in FIGS. 3 and 4. During assembly of each standoff 11, the lower portions of the first and second pairs of legs 21, 22 and 23, 24 are retracted inwardly to facilitate insertion through an opening 54 in the second board 52. After insertion, the first and second pairs of legs 21, 22 and 23, 24, are allowed to extend radially producing tight engagement between the lower portions thereof and an inner perimeter 55 of the opening 54. In addition, the outwardly directed flanges 41 contact a lower surface 56 of the second board 52 facing opposite to the first board 51. A conventional impact tool then is inserted through the opening 54 into the body 12 and actuated to induce further outer expansion of the first and second pairs of legs 21, 22 and 23, 24. Such expansion produces penetration of the inner perimeter 55 of the opening 54 by the engagement tabs 42, 43 of the second pair of legs 23, 24 and the engagement extremities 35, 36 of the first pair of legs 21, 22.

The printed circuit board 51 then is placed on the assembled body members 12 and supported by contact between the collars 31 thereof and a lower surface of the board 51 facing the second board 52. After proper positioning, an opening 58 in the first board 51 is aligned with the collar 31 in each body member 12. A screw fastener 13 then is inserted through each opening 58 and turned to provide threaded engagement of the shank portion 28 with the fastener edge 32 and fastener tabs 46, 47 of each body member 12. Each fastener screw 13 is tightened to produce secure engagement between its slotted head 27 and an upper surface 59 of the first board 51 facing away from the second board 52. During the assembly of the fastener screws 13, the fastener edge 32 maintains axial alignment of the shank portion 28 with the fastener tabs 46, 47 and engagement therebetween produces a radially outward expansion force on the first pair of legs 21, 22. That outward force maintains the previously induced penetration of the second board 52 by the engagement extremity portions 35, 36 of the first pair of legs 21, 22.

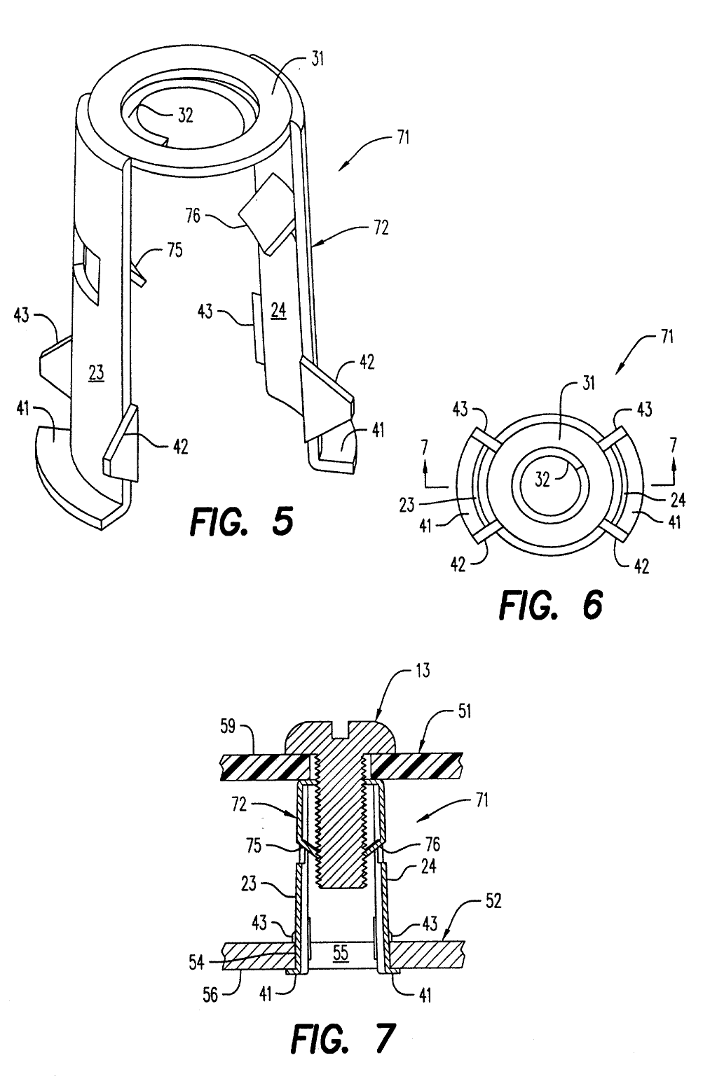

Illustrated in FIGS. 5-7 is another standoff embodiment 71 including a body member 72 and a screw fastener 13. Portions of the standoff 71 which are the same as those of the standoff 11 have been given the same reference numerals. The standoff 71 is substantially identical to the standoff 11 except for an absence of the diametrically opposed second pair of legs 23, 24, thereof. One other difference is the formation in the legs 23, 24, respectively, of inwardly directed fastener tabs 75, 76 arranged and dimensioned for threaded engagement with the shank portion 28 of the screw fastener 13. The standoff 71 is used to provide separation between first and second boards 51, 52 in the same manner as described above for the standoff 11.

Obviously, many modifications and variations of the present invention are possible in light of the above teachings. It is to be understood, therefore, that the invention can be practiced otherwise than as specifically described.

What is claimed is:

1. A circuit board standoff comprising:
a fastener means; and
a body means for disposition axially between first and second boards and comprising an upper portion for contacting the first board, fastener portions for engaging said fastener means to secure said body means to the first board, and outwardly directed edge engagement portions adapted to be forced into penetrating engagement with the second board.

2. A standoff according to claim 1 wherein said body means further comprises a plurality of legs having lower portions shaped and arranged to be tightly received by an opening in the second board and defining said engagement portions.

3. A standoff according to claim 2 wherein said engagement portions are defined by extremity portions of said legs, said extremity portions being shaped and arranged for outward expansion to penetrate perimeter portions of the opening in the second board.

4. A standoff according to claim 3 wherein said legs include at least one leg in which said lower portion thereof is outwardly convex and has opposite edge portions defining said extremity portions.

5. A standoff according to claim 3 wherein said legs include at least one leg in which said lower portion thereof defines outwardly directed engagement tab means defining said extremity portions.

6. A standoff according to claim 5 wherein said legs include at least one leg in which said lower portion thereof is outwardly convex and has opposite edge portions further defining said extremity portions.

7. A standoff according to claim 3 wherein said legs include at least one leg in which said lower portion thereof defines outwardly directed flange means shaped and arranged to engage a surface of the second board facing opposite to the first board.

8. A standoff according to claim 7 wherein said legs include at least one leg in which said lower portion thereof is outwardly convex and has opposite edge portions defining said extremity portions.

9. A standoff according to claim 8 wherein said legs include at least one leg in which said lower portion thereof defines outwardly directed engagement tab means further defining said extremity portions.

10. A standoff according to claim 2 wherein said fastener means is a screw having a threaded shank engaging said fastener portions and a head for contacting a surface of the first board facing opposite to the second board.

11. A standoff according to claim 10 wherein said fastener portions comprise an inwardly directed annular collar in said upper portion and having an inner fastener edge threadedly engaged with said threaded shank.

12. A standoff according to claim 10 wherein said fastener portions comprise inwardly directed fastener tab means formed in an intermediate portion of said body means and threadedly engaged with said threaded shank.

13. A standoff according to claim 12 wherein said fastener portions further comprise an inwardly directed annular collar in said upper portion and having an inner fastener edge threadedly engaged with said threaded shank.

14. A standoff according to claim 2 wherein said fastener means is shaped and arranged to produce outward expansion of said legs in response to engagement with said fastener portions.

15. A standoff according to claim 14 wherein said engagement portions are defined by extremity portions of said legs, said extremity portions being shaped and arranged to penetrate perimeter portions of the opening in the second board.

16. A standoff according to claim 15 wherein said legs include at least one leg in which said lower portion thereof is outwardly convex and has opposite edge portions defining said extremity portions.

17. A standoff according to claim 15 wherein said legs include at least one leg in which said lower portion thereof defines outwardly directed engagement tab means further defining said extremity portions.

18. A standoff according to claim 14 wherein said fastener means is a screw having a threaded shank engaging said fastener portions and a head for contacting a surface of the first board facing opposite to the second board.

19. A standoff according to claim 18 wherein said fastener portions comprise inwardly directed fastener tab means formed in an intermediate portion of said body means and threadedly engaged with said threaded shank.

20. A standoff according to claim 19 wherein said fastener portions further comprise an inwardly directed annular collar in said upper portion and having an inner fastener edge threadedly engaged with said threaded shank.

21. A standoff according to claim 20 wherein said engagement portions are defined by extremity portions of said legs, said extremity portions being shaped and arranged to penetrate perimeter portions of the opening in the second board.

22. A standoff according to claim 21 wherein said legs include at least one leg in which said lower portion thereof is outwardly convex and has opposite edge portions defining said extremity portions.

23. A standoff according to claim 22 wherein said legs include at least one leg in which said lower portion thereof defines outwardly directed engagement tab means further defining said extremity portions.

24. A standoff according to claim 1 wherein said body means is a substantially cylindrical stamped unitary member formed from an electrically conductive material.
